(19) United States
(12) Patent Application Publication
(10) Pub. No.: US 2025/0258511 A1
(43) Pub. Date: Aug. 14, 2025

(54) SEMICONDUCTOR DEVICE

(71) Applicant: Renesas Electronics Corporation, Tokyo (JP)

(72) Inventors: Hajime HAYASHIMOTO, Tokyo (JP); Kenji YOSHITA, Tokyo (JP)

(73) Assignee: Renesas Electronics Corporation, Tokyo (JP)

(21) Appl. No.: 19/047,959

(22) Filed: Feb. 7, 2025

(30) Foreign Application Priority Data
Feb. 9, 2024 (JP) 2024-018375

(51) Int. Cl. G05F 3/26; H03F 1/34

(52) U.S. Cl. CPC G05F 3/267; H03F 1/342

(57) ABSTRACT

A semiconductor device includes: a first electric-current generator circuit generating a first electric current having a positive temperature coefficient and not having dependency on a first power-supply voltage; a second electric-current generator circuit generating a second electric current having a negative temperature coefficient and not having dependency on the first power-supply voltage; and a third electric-current generator circuit generating a third electric current neither having dependency on the temperature nor the first power-supply voltage, based on the first electric current and the second electric current.

### CROSS-REFERENCE TO RELATED APPLICATION

This application claims priority under 35 U.S.C. § 119 to Japanese Patent Application No. 2024-018375 filed on Feb. 9, 2024. The disclosure of Japanese Patent Application No. 2024-018375, including the specification, drawings and abstract, is incorporated herein by reference in its entirety.

### BACKGROUND

The present invention relates to a semiconductor device, and more particularly relates to a semiconductor device generating a temperature-compensated electric current.

There is disclosed a technique listed below.
[Patent Document 1] Japanese Unexamined Patent Application Publication No. 2004-206633

The Patent Document 1 discloses a technique of generating a reference voltage compensated in terms of temperature and power-supply voltage and that is equal to or lower than 1.2 V.

### SUMMARY

A reference-voltage generator circuit described in the Patent Document 1 has a problem that is failure to generate a voltage compensated in terms of temperature and power-supply voltage and that is equal to or higher than 1.2 V.

The present disclosure has been designed to solve such a problem, and an objective of the present disclosure is to achieve a semiconductor device generating an electric current compensated in terms of temperature and power-supply voltage.

Other objects and novel characteristics will become apparent from the description of the present specification and the drawings.

A semiconductor device according to an embodiment includes: a first electric-current generator circuit generating a first electric current having a positive temperature coefficient and not having dependency on a first power-supply voltage; a second electric-current generator circuit generating a second electric current having a negative temperature coefficient and not having dependency on the first power-supply voltage; and a third electric-current generator circuit generating a third electric current neither having dependency on the temperature nor the first power-supply voltage, based on the first electric current and the second electric current.

According to the embodiment, a semiconductor device generating an electric current compensated in terms of temperature and power-supply voltage can be provided.

### BRIEF DESCRIPTIONS OF THE DRAWINGS

FIG. 1 is a circuit diagram showing a configuration of a semiconductor device according to a first embodiment.

FIG. 2 is a graph showing dependency on temperature for an electric current according to the first embodiment.

FIG. 3 is a circuit diagram showing a configuration of a semiconductor device according to a second embodiment.

FIG. 4 is a graph showing dependency on temperature for a reference voltage according to the second embodiment.

FIG. 5 is a diagram for explaining one of effects of the second embodiment.

FIG. 6 is a circuit diagram showing a configuration of a semiconductor device according to a third embodiment.

FIG. 7 is a graph showing dependency on temperature for a reference voltage according to the third embodiment.

### DETAILED DESCRIPTION

The following description and drawings are appropriately omitted or simplified for clear explanation. The same components are denoted with the same reference signs throughout each drawing, and the repetitive description thereof is omitted as needed.

### First Embodiment

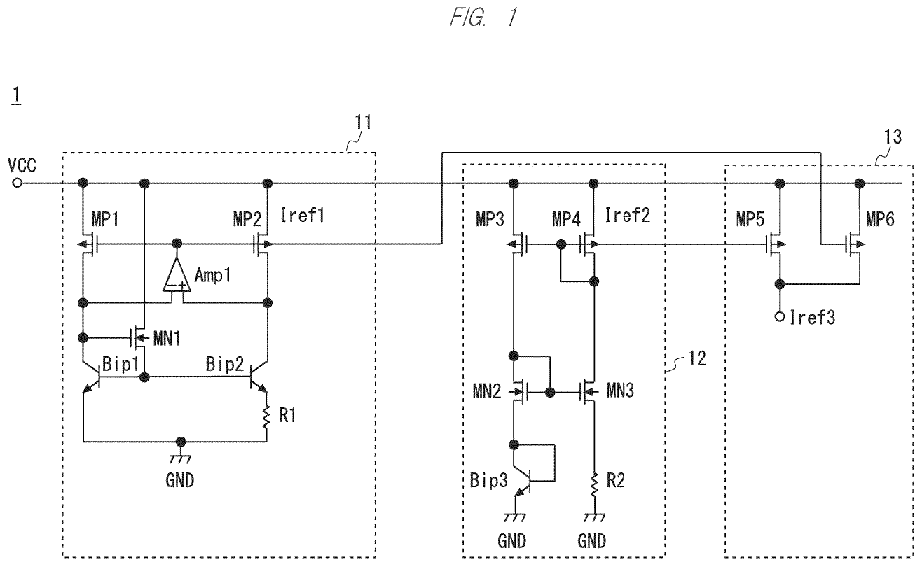

FIG. 1 is a circuit diagram showing a configuration of a semiconductor device 1 according to a first embodiment. The semiconductor device 1 includes electric-current generator circuits 11, 12 and 13. The electric-current generator circuits 11, 12 and 13 are also referred to as first electric-current generator circuit, second electric-current generator circuit and third electric-current generator circuit, respectively.

The electric-current generator circuit 11 includes p-channel type MOS (Metal-Oxide Semiconductor) transistors MP1 and MP2, an n-channel type MOS transistor MN1, npn-type bipolar transistors Bip1 and Bip2, a resistor R1 and an amplifier Amp1.

The MOS transistor MP1 and the bipolar transistor Bip1 are connected in series between a power-supply voltage VCC and a ground voltage GND. The power-supply voltage VCC is also referred to as first power-supply voltage. The MOS transistor MP2, the bipolar transistor Bip2 and the resistor R1 are connected in series, and connected in parallel to the MOS transistor MP1 and the bipolar transistor Bip1. Gates of the bipolar transistors Bip1 and Bip2 are connected to a source of the MOS transistor MN1, and a gate of the MOS transistor MN1 is connected to a connection node between the MOS transistor MP1 and the bipolar transistor Bip1. A drain of the MOS transistor MN1 is connected to the power-supply voltage VCC. A negative-input terminal of the amplifier Amp1 is connected to a connection node between the MOS transistor MP1 and the bipolar transistor Bip2. A positive-input terminal of the amplifier Amp1 is connected to a connection node between the MOS transistor MP2 and the bipolar transistor Bip2. An output terminal of the amplifier Amp1 is connected to gates of the MOS transistors MP1 and MP2. The amplifier Amp1 controls the MOS transistors MP1 and MP2 such that a voltage of the connection node connected to the positive-input terminal and a voltage of the connection node connected to the negative-input terminal are equal to each other.

If device sizes, in other words, gate lengths and gate widths of the MOS transistors MP1 and MP2 are equal to each other, an electric current (also referred to as first electric current) Iref1 flowing between the source and the drain of the MOS transistor MP2 of the electric-current generator circuit 11 is expressed by the following equation (1). A temperature coefficient ΔIref1/ΔT of the electric current Iref1 is expressed by the following equation (2).

$$Iref = 1 / R 1 * ( kT / q ) * ( ln M ) \qquad Equation ( 1 )$$

$$Δ Iref 1 / Δ T = ( 1 / R 1 ) * ( k / q ) * ( ln M ) \qquad Equation ( 2 )$$

The term “M” herein represents a ratio of an emitter area of the bipolar transistor Bip1 and an emitter area of the bipolar transistor Bip2. The elementary charge is “q=1.6*10\hat{ }(−19) [C]”, the Boltzmann constant is “k=1.38*10\hat{ }(−23) [J/K]”, and the term “T” represents an absolute temperature [K]. Note that a resistance value of the resistor R1 is assumed to be “R1”.

From the equation (2), it is found that an equation (3) “ΔIref1/ΔT>0” is established.

The electric-current generator circuit 12 includes p-channel type MOS transistors MP3 and MP4, n-channel type MOS transistors MN2 and MN3, an npn-type bipolar transistor Bip3 and a resistor R2.

The MOS transistor MP3, the MOS transistor MN1 and the bipolar transistor Bip3 are connected in series between the power-supply voltage VCC and the ground voltage GND. A collector and a base of the bipolar transistor Bip3 are connected to each other. The MOS transistor MP4, the MOS transistor MN3 and the resistor R2 are connected in series, and connected in parallel to the MOS transistor MP3, the MOS transistor MN1 and the bipolar transistor Bip3. Gates of the MOS transistors MP3 and MP4 are connected to a connection node between the MOS transistor MP4 and the MOS transistor MN3. Gates of the MOS transistors MN2 and MN3 are connected to a connection node between the MOS transistor MP3 and the MOS transistor MN2. The MOS transistors MP3, MP4, MN2 and MN3 configure a current mirror circuit. If the device sizes of the MOS transistors MP3, MP4, MN1 and MN2 are equal to one another, the electric currents flowing in the MOS transistors MP3, MP4, MN1 and MN2 are equal to one another. A voltage of the connection node between the MOS transistors MN2 and the bipolar transistor Bip3 is equal to a voltage of the connection node between the MOS transistors MN3 and the resistor R2.

If the device sizes of the MOS transistors MP3, MP4, MN1 and MN2 are equal to one another, the electric current Iref2 (also referred to as second electric current) flowing in the MOS transistor MP4 of the electric-current generator circuit 12 is expressed by the following equation (4). Its temperature coefficient ΔIref2/ΔT is expressed by the following equation (5).

$$Iref 2 = ( VBE\_Bip 3 ) / R 2 \qquad Equation ( 4 )$$

$$Δ Iref 2 / Δ T = ( ( Δ VBE\_Bip 3 ) / Δ T ) / R 2 \qquad Equation ( 5 )$$

The term “VBE_Bip3” herein represents a voltage between the base and the emitter of the bipolar transistor Bip3. Note that a resistance value of the resistor R2 is assumed to be “R2”.

Because of “(ΔVBE_Bip3)/ΔT<0”, the following equation (6) is derived from the equation (5).

$$Δ Iref 2 / Δ T < 0 \qquad Equation ( 6 )$$

The electric-current generator circuit 13 includes p-channel type MOS transistors MP5 and MP6. A source of the MOS transistor MP5 is connected to the power-supply voltage VCC, and a gate of the MOS transistor MP5 is connected to a gate of the MOS transistor MP4. The MOS transistor MP6 is connected in parallel to the MOS transistor MP5, and a gate of the MOS transistor MP6 is connected to a gate of the MOS transistor MP2. The MOS transistor MP5 copies the electric current Iref2 at a predetermined mirror ratio, the electric current flowing between the source and the drain of the MOS transistor MP4. The MOS transistor MP6 copies the electric current Iref1 at a predetermined mirror ratio, the electric current flowing between the source and the drain of the MOS transistor MP2. The electric current flowing between the source and the drain of the MOS transistor MP5 and the electric current flowing between the source and the drain of the MOS transistor MP6 are synthesized to generate an electric current Iref3 (also referred to as third electric current).

The electric current Iref3 is expressed by the following equation (7). Its temperature coefficient ΔIref3/ΔT is expressed by the following equation (8).

$$Iref 3 = A * Iref 1 + B * Iref 2 \qquad Equation ( 7 )$$

$$Δ Iref 3 / Δ T = A * Δ Iref 1 / Δ T + B * Δ Iref 2 / Δ T \qquad Equation ( 8 )$$

The term “A” herein represents the mirror ratio between the MOS transistors MP2 and MP6, and the term “B” herein represents the mirror ratio between the MOS transistors MP4 and MP5.

By appropriately setting the terms “A” and “B”, the electric current Iref3 not having dependency on temperature is derived from the equations (8), (3) and (6). Also, the equation (8) does not include a term relating to the power-supply voltage VCC. Therefore, the semiconductor device 1 according to the first embodiment can generate the electric current neither having dependency on the power-supply voltage nor the temperature.

Next, a case of setting the following condition (1) will be specifically explained.

$$R 1 = 50 [ k Ω ] , M = 8 , R 2 = 900 [ k Ω ] , A = 2 , B = 4 \qquad Condition ( 1 )$$

The following equations (1′), (2′), (4′), (5′), (7′), and (8′) are derived from substitution of the numerical values of the condition (1) into the equations (1), (2), (4), (5), (7), and (8).

$$Iref 1 = ( 1 / 50 K ) * ( kT / q ) * ( ln 8 ) = 1 [ μ A ] \qquad Equation ( {1}^{′} )$$

$$Δ Iref 1 / Δ T = ( 1 / 50 K ) * ( k / q ) * ( ln 8 ) = 3.6 [ nA / ° C . ] ] \qquad Equation ( {2}^{′} )$$

$$Iref 2 = ( VBE\_Bip3 ) / 900 K = 770 [ nA ] \qquad Equation ( {4}^{′} )$$

$$Δ Iref 2 / Δ T = ( Δ VBE / Δ T ) / 900 K = 162 [ mV / ° C . ] / 900 [ k Ω ] = 18 [ nA / ° C . ] \qquad Equation ( {5}^{′} )$$

$$Iref 3 = 2 * Iref 1 + 4 * Iref 2 = 5 [ μA ] \qquad Equation ( {7}^{′} )$$

$$Δ Iref 3 / Δ T + 4 * Δ Iref 2 / Δ T = 0 [ A / ° C . ] \qquad Equation ( {8}^{′} )$$

The result “(ΔVBE/ΔT)=−1.62 [mV/° C.]” herein is set from simulation results for the temperature coefficient of the VBE in a case of “Emitter electric current: IE=770 nA”.

Since the temperature coefficient in the equation (8′) is 0, it is verified that the electric current not having dependency on temperature can be generated.

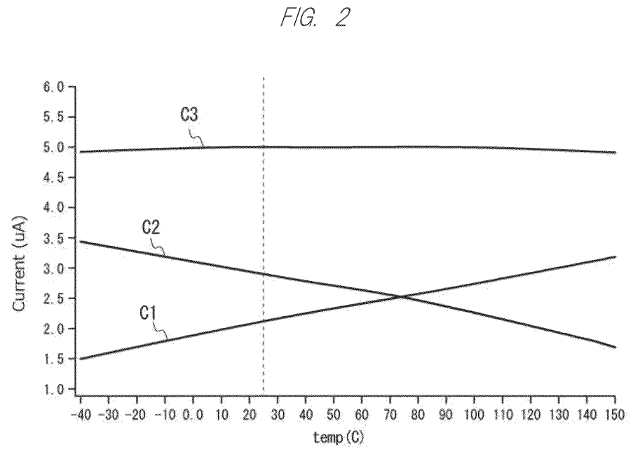

FIG. 2 shows the simulation results in the case of setting of the condition (1). Its horizontal axis represents the temperature, and its vertical axis represents the electric current. The term “C1” represents the electric current flowing between the source and the drain of the MOS transistor MP6, in other words, represents the dependency on temperature for “Iref1*4”. The term “C2” represents the electric current flowing between the source and the drain of the MOS transistor MP5, in other words, represents the dependency on temperature for “Iref2*4”. The term “C3” represents the dependency on temperature for “Iref3”. A vertically-extending dotted line represents 25° C. The temperature of 25° C. meets “Iref1*2=2 [μA]”, “Iref2*4=3 [μA]” and “Iref3=5 [μA]”. It is found that the Iref1 has the positive dependency on temperature, the Iref12 has the negative dependency on temperature, and the Iref3 has no dependency on temperature.

### Second Embodiment

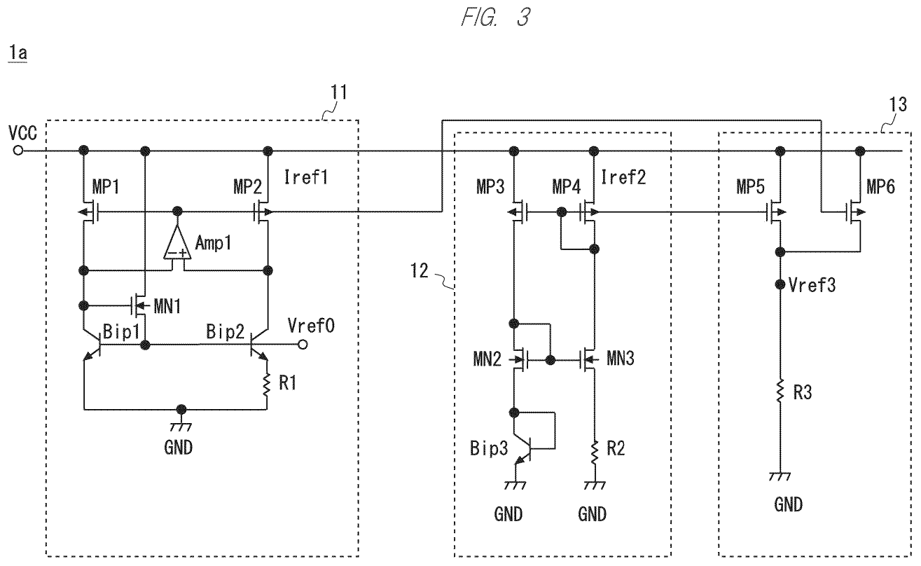

FIG. 3 is a circuit diagram of a semiconductor device 1a according to a second embodiment. The semiconductor device 1a generates a reference voltage neither having the dependency on the temperature nor the power-supply voltage VCC, based on the electric current Iref3.

In comparison between FIGS. 1 and 3, an electric-current generator circuit 13 of the semiconductor device 1a further includes a resistor R3. One end of the resistor R3 is connected to a connection node between the MOS transistor MP5 and he MOS transistor MP6. The other end of the resistor R3 is connected to the ground voltage GND. When the electric current Iref3 flows in the resistor R3, a reference voltage Vref3 is generated on one end of the resistor R3.

The reference voltage Vref3 is expressed by the following equation (9). Its temperature coefficient “ΔVref3/ΔT” is expressed by the following equation (10).

$$Vref 3 = Iref 3 * R 3 \qquad Equation ( 9 )$$

$$Δ Vref 3 / Δ T = ( Δ Iref 3 / Δ T ) * R 3 \qquad Equation ( 10 )$$

As described above, by appropriately setting the terms “A” and “B” in the equation (8), the electric current Iref3 having the temperature coefficient “ΔIref3/ΔT” in the following equation (11) and not having the dependency on temperature can be achieved.

$$Δ Iref 3 / Δ T = 0 \qquad Equation ( 11 )$$

It is found that “ΔVref3/ΔT=0” is achieved by substitution of the equation (11) into the equation (10).

As described above, it is found that the optional reference voltage Vref compensated in terms of the temperature and the power-supply voltage can be generated by appropriately selecting the resistance value of the resistor R3. Particularly, the reference voltage Vref that is equal to or higher than 1.2 V can be generated.

Next, a case of setting the following condition (2) in addition to the condition (1) will be specifically explained.

$$R 3 = 500 [ k Ω ] \qquad Condition ( 2 )$$

The following equation (9′) is derived from substitution of the condition (2) and the Iref3 calculated from the equation (7′) into the equation (9). And, the following equation (10′) is derived from substitution of “ΔIref3/ΔT=0” in the equation (11) into the equation (10).

$$Vref 3 = Iref 3 * R 3 = 5 [ μA ] * 500 [ kΩ ] = 2.5 [ V ] \qquad Equation ( {9}^{′} )$$

$$Δ Vref 3 / Δ T = ( Δ Iref 3 / Δ T ) * R 3 = 0 * 500 [ kΩ ] = 0 [ V / ° C . ] \qquad Equation ( {10}^{′} )$$

It is verified that the reference voltage Vref having the temperature coefficient of 0 in the equation (10) and not having the dependency on temperature can be generated. With reference to the equation (9′), it is verified that the reference voltage that is equal to or higher than 1.2 V can be generated.

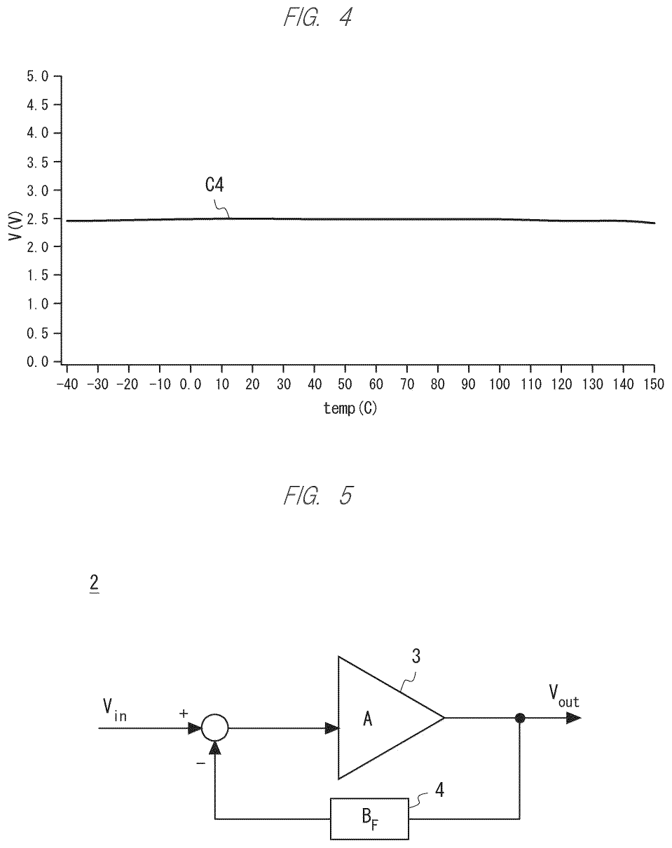

FIG. 4 shows simulation results in a case of setting the condition (1) and the condition (2). Its horizontal axis represents the temperature, and its vertical axis represents the voltage. The term “C4” represents the dependency on temperature for the reference voltage Vref. The reference voltage Vref is about 2.5 V to be equal to or larger than 1.2 V. From the simulation results, it is found that the second embodiment can generate the reference voltage not having the dependency on temperature and being equal to or larger than 1.2 V.

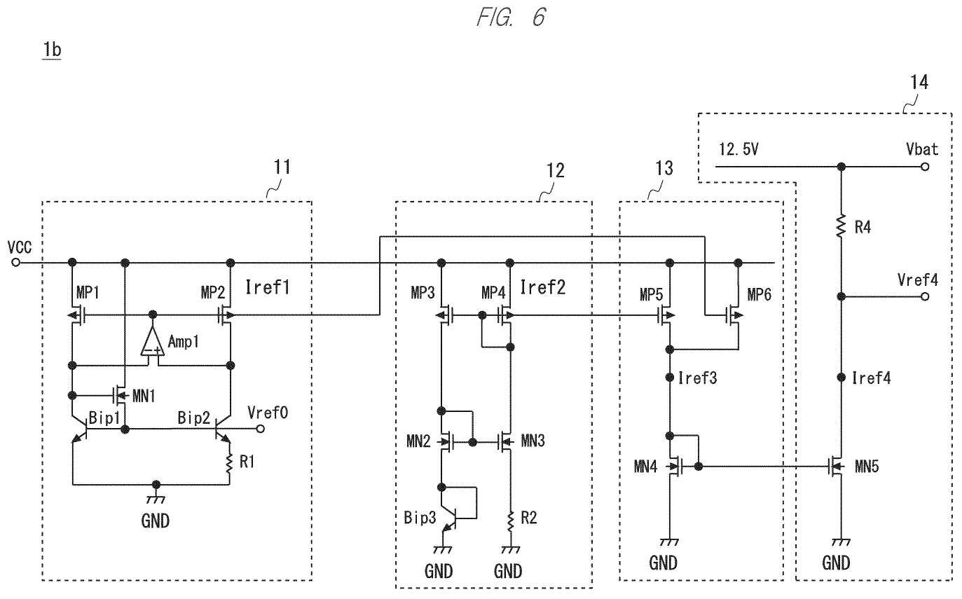

Next, with reference to FIG. 5, one of effects caused by the generation of the optional reference voltage neither having the dependency on the temperature nor the power-supply voltage and being equal to or larger than 1.2 V will be explained. A negative-feedback amplifier circuit 2 includes an amplifier circuit 3 and a feedback circuit 4. The feedback circuit 4 returns a part of a voltage amplified by the amplifier circuit 3 to an input of the amplifier circuit 3 in the opposite phase. Regarding an input voltage Vin and an output voltage Vout of the negative-feedback amplifier circuit 2, the following equation (12) is established.

$$Vout / Vin = A / ( 1 + {β}_{F} * A ) \qquad Equation ( 12 )$$

The term “β_{F}” herein represents a feedback rate of the feedback circuit 4, and the term “A” herein represents a gain of the amplifier circuit 3.

Generally, the term “A” is sufficiently larger than 1, and is equal to or larger than 1000 times. Therefore, the equation (12) can be deformed to be the following equation (13).

$$Vout / Vin = A / ( 1 + {β}_{F} * A ) = 1 / {β}_{F} \qquad Equation ( 13 )$$

It is known that the larger the term “β_{F}” configuring the equation (13) is, the lower the distortion is, and the higher the speed is. For example, if the reference voltage “Vref=2.5 V” in the second embodiment is supplied as the Vin in order to provide “Vout=2.5 [V]”, a relation “β_{F}=1” is derived from the equation (13). On the other hand, if the reference voltage “Vref=1.25 V” in the related art is supplied as the Vin, a relation “β_{F}=0.5” is established.

Since the feedback amount β_{F} of the negative-feedback amplifier circuit can be set to large, the second embodiment can achieve the low distortion and the high speed of the negative-feedback amplifier circuit.

### Third Embodiment

FIG. 6 is a circuit diagram of a semiconductor device 1b according to a third embodiment. The semiconductor device 1b generates a reference voltage with reference to a power-supply voltage Vbat, based on the electric current Iref3.

In comparison between FIGS. 1 and 6, the semiconductor device 1b further includes a reference-voltage generator circuit 14 with reference to the power-supply voltage Vbat. The reference-voltage generator circuit 14 includes an n-channel type MOS transistor MN5 and a resistor R4. The electric-current generator circuit 13 further includes an n-channel type MOS transistor MN4.

The MOS transistor MN4 is arranged between the ground voltage GND and a connection node between the MOS transistor MP3 and the MOS transistor MP4. The resistor R4 and the MOS transistor MN5 are connected in series between the power-supply voltage Vbat and the ground voltage GND. The power-supply voltage Vbat is also referred to as second power-supply voltage. Gates of the MOS transistors MN4 and MN5 are connected to a drain of the MOS transistor MN4. One end of the resistor R4 is connected to the power-supply voltage Vbat, and the reference voltage Vref4 is generated on the other end of the resistor R4.

The power-supply voltage Vbat is, for example, a voltage of a battery mounted on a vehicle. The MOS transistors MN4 and MN5 configure a current mirror circuit, and the MOS transistor MN5 makes a flow of a mirror electric current Iref4 of the electric current Iref3 to the resistor R4. As a result, a reference voltage Vref4 is generated on a connection node between the resistor R4 and the MOS transistor MN5.

The reference voltage Vref4 is expressed by the following equation (14). Its temperature coefficient “ΔVref4/ΔT” is expressed by the following equation (15).

$$Vref 4 = Vbat - ( Iref 4 * R 4 ) \qquad Equation ( 14 )$$

$$Vout / Vin = Δ Vref 4 / Δ T = ( Δ Iref 4 / Δ T ) * R 4 \qquad Equation ( 15 )$$

The term “Iref4” herein represents the mirror electric current of the electric current Iref3 as described above. Since a relation “ΔIref3/ΔT=0” in the equation (11) is established, a relation “ΔIref4/ΔT=0” is also established. Therefore, from the equation (15), it is also found that a relation “ΔVref4/ΔT=0” is achieved.

Therefore, the third embodiment can provide the optional reference voltage Vref4 compensated in terms of temperature with reference to the power-supply voltage Vbat different from the power-supply voltage VCC, by appropriately selecting the resistor R4. The power-supply voltage Vref4 does not depend on the power-supply voltage VCC.

Next, a case of setting the following condition (3) in addition to the condition (1) will be specifically explained.

$$R 4 = 200 [ k Ω ] , Vbat = 12.5 [ V ] \qquad Condition ( 3 )$$

The following equation (14′) is derived from substitution of the condition (3) into the equation (14). The following equation (15′) is derived from substitution of the condition (3) into the equation (15). Because of a relation “Iref3=5 [μA]” in the equation (7′), a relation “Iref4=5 [μA]” is set.

$$Vref 4 = Vbat - ( Iref 4 * R 4 ) = 12.5 [ V ] - 5 [ μA ] * 200 [ k Ω ] = 11.5 \qquad Equation ( {14}^{′} )$$

$$Δ Vref 4 / Δ T = ( Δ Iref 4 / Δ T ) * R 4 = 0 * 200 [ k Ω ] = 0 \qquad Equation ( {15}^{′} )$$

It is verified that the reference Voltage Vref4 having the temperature coefficient of 0 in the equation (15′) and not having the dependency on temperature can be generated.

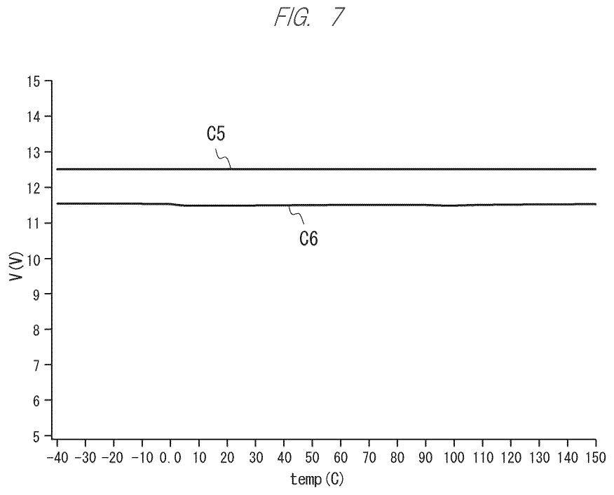

FIG. 7 shows simulation results in a case of setting the condition (1) and the condition (3). Its horizontal axis represents the temperature, and its vertical axis represents the voltage. The term “C5” represents the power-supply voltage Vbat, and the term “C6” represents the dependency on temperature for the reference voltage Vref. The power-supply voltage Vbat is 12.5 V, and the reference voltage Vref4 is about 11.5 V. From the simulation results, it is found that the third embodiment can generate the reference voltage Vref4 not having the dependency on temperature.

In the third embodiment, the mirror electric current Iref4 of the electric current Iref3 generated with reference to the ground voltage GND is flown in the resistor R4 connected to the power-supply voltage Vbat. As a result, the third embodiment can generate the reference voltage Vref with reference to the power-supply voltage Vbat.

Generally, in order to generate the reference voltage with reference to the power-supply voltage Vbat, it is necessary to prepare a reference voltage source with reference to the power-supply voltage Vbat as different from a reference voltage source with reference to the ground voltage GND. In the third embodiment, it is unnecessary to prepare it, and therefore, the circuit area and the consumed electric current can be reduced.

The reference-voltage generator circuit 14 may be included in a semiconductor device different from the semiconductor device including the electric-current generator circuits 11, 12 and 13. For example, the semiconductor device including the reference-voltage generator circuit 14 may be an intelligent power device (IPD) including the power MOSFET, and the semiconductor device including the electric-current generator circuits 11, 12 and 13 may be a MCU controlling the IPD. The IPD may include a controller circuit connected to the battery power supply (Vbat) and controlling the power MOSFET. If a reference voltage is necessary for the controller circuit in this IPD, the IPD needs to include a reference voltage source with reference to the battery power supply Vbat, such as a bandgap reference circuit. In this case, the reference voltage source included in the IPD needs to be made of a high withstand voltage device. However, the third embodiment can generate the reference voltage with reference to the battery power supply Vbat by using a simpler circuit configuration than the bandgap reference circuit as the reference-potential generator circuit included in the IPD. As a result, the circuit area and the consumed electric current of the IPE can be reduced.

In the foregoing, the invention made by the inventors of the present application has been concretely described on the basis of the embodiments. However, the present invention is not limited to the foregoing embodiments, and various modifications can be made within the scope of the present invention.

For example, a regulator according to the embodiments may be configured such that the conductivity types (p-type or n-type) of the semiconductor substrate, the semiconductor layer, the diffusion layer (diffusion region) and the like are inverted. Therefore, if either one of the n-type and the p-type is set as a first conductivity type while the other conductivity type is set as a second conductivity type, the first conductivity type may be the p-type while the second conductivity type may be the n-type, and conversely, the first conductivity type may be the n-type while the second conductivity type may be the p-type.

What is claimed is:

1. A semiconductor device comprising:
a first electric-current generator circuit generating a first electric current having a positive temperature coefficient and not having dependency on a first power-supply voltage;
a second electric-current generator circuit generating a second electric current having a negative temperature coefficient and not having dependency on the first power-supply voltage; and
a third electric-current generator circuit generating a third electric current neither having dependency on the temperature nor the first power-supply voltage, based on the first electric current and the second electric current.

2. The semiconductor device according to claim 1,
wherein the third electric current is generated by synthesis of an electric current copied at a first mirror ratio from the first electric current and an electric current copied at a second mirror ratio from the second electric current, and
the first mirror ratio and the second mirror ratio are set such that a temperature coefficient of the third electric current is zero.

3. The semiconductor device according to claim 1,
wherein a reference voltage neither having dependency on the temperature nor the first power-supply voltage is generated based on the third electric current.

4. The semiconductor device according to claim 3,
wherein the reference voltage is larger than 1.2 V.

5. The semiconductor device according to claim 3 further comprising
a negative-feedback amplifier circuit amplifying the reference voltage.

6. The semiconductor device according to claim 5,
wherein a feedback rate of the negative-feedback amplifier circuit is larger than 0.5.

7. The semiconductor device according to claim 3 further comprising
a current mirror circuit making flow of an electric current copied from the third electric current to a resistor, one end of which is connected to a second power-supply voltage,
wherein the reference voltage is generated on the other end of the resistor.

8. The semiconductor device according to claim 7,
wherein the second power-supply voltage is a battery voltage.

9. The semiconductor device according to claim 1,
wherein the second electric current is generated based on a voltage between a base and an emitter of a bipolar transistor.
